(19) United States
(12) Patent Application Publication
(10) Pub. No.: US 2026/0235420 A1
(43) Pub. Date: Aug. 13, 2026

(54) SENSOR DRIVE DEVICE AND METHOD FOR OPERATING A CAPACITIVE SENSOR

(71) Applicant: Robert Bosch GmbH, Stuttgart (DE)

(72) Inventors: Amin Jemili, Kusterdingen (DE); Steffen Becker, Coswig (DE)

(21) Appl. No.: 19/471,859

(22) PCT Filed: Apr. 17, 2024
(86) PCT No.: PCT/EP2024/060449

§ 371 Date: Oct. 2, 2025

(30) Foreign Application Priority Data
Apr. 26, 2023 (DE) 10 2023 203 854.4

(51) Int. Cl. G01D 5/24; G01P 15/125; H04R 1/46

(52) U.S. Cl. CPC G01D 5/24; G01P 15/125; H04R 1/46

(57) ABSTRACT

A sensor drive device for a capacitive sensor. The sensor drive device is electrically linked to a drive node of the capacitive sensor so that during a first control phase of the sensor drive device, a charge flow between the sensor drive device and the drive node is triggerable using the sensor drive device in such a way that a predefined target voltage is able to be applied to at least one measuring capacitor, electrically linked to the drive node, of the capacitive sensor, which is dischargeable during a second control phase of the sensor drive device.

### FIELD

The present invention relates to a sensor drive device for a capacitive sensor. The present invention also relates to a capacitive sensor. In addition, the present invention relates to a method for operating a capacitive sensor.

### BACKGROUND INFORMATION

FIG. 1 is a schematic representation of a conventional capacitive sensor device from the related art.

The conventional capacitive sensor device 10 shown schematically in FIG. 1 comprises at least one measuring capacitor 12 whose sensor capacitance Cₛ varies as a function of a variable to be detected or measured by means of the capacitive sensor device 10. The conventional capacitive sensor device 10 is static, i.e., at least one seismic mass (not outlined) of the at least one measuring capacitor 12 of the capacitive sensor device 10 does not execute any modulated intrinsic motion.

According to equation (Eq. 1), therefore, a measuring current Iₘ which can be evaluated by means of an evaluation unit 14 of the capacitive sensor device 10 flows only when a measurement voltage Uₘ applied to the at least one measuring capacitor 12 alternates:

$${I}_{m} = \frac{d ( {C}_{s} * {U}_{m} )}{dt} \qquad ( Eq . 1 )$$

Therefore, before each measuring time interval of the capacitive sensor device 10 according to the related art, what is referred to as a target voltage must first be applied to the at least one measuring capacitor 12 in order to ensure the measuring current Iₘ during the subsequent measurement time interval.

To apply the desired target voltage to the at least one measuring capacitor 12, a drive node 16 of the conventional capacitive sensor device 10, to which the at least one measuring capacitor 12 is electrically linked, is electrically connected to an amplifier 20 of the capacitive sensor device 10 by means of a switching device 18 of the capacitive sensor device 10 during a first phase. During the first phase, the target voltage is then stabilized with a desired precision using the amplifier 20. During a second phase following the first phase, the drive node 16 is electrically linked to a ground 22 via the switching device 18, so that the at least one measuring capacitor 12 is discharged by the flow of the measuring current Iₘ. During operation of the capacitive sensor device 10, the first phase and the second phase alternate.

As can be seen in FIG. 1, the amplifier 20 uses a differential amplifier 20a to settle the target voltage with the desired precision, wherein a first signal input of the differential amplifier 20a is electrically linked via a feedback line 20b with a feedback factor β to a signal output of the differential amplifier 20a, and a reference voltage Vᵣ is applied to a second signal input of the differential amplifier 20a. The signal output of the differential amplifier 20a is also electrically linked to the switching device 18. According to equation (Eq. 2), a settling time t is required to settle the target voltage by means of the amplifier 20 with the desired precision, for which time the following applies:

$$τ = \frac{{C}_{+}}{β * g} \qquad ( Eq . 2 )$$

where g is a conductance of the amplifier 20, β is the feedback factor of the amplifier 20, and C₊ is a sum of the sensor capacitance Cₛ and a parasitic capacitance Cₚ of at least one interference capacitor 24 of the conventional capacitive sensor device 10.

As can be seen from equation (Eq. 2), the amplifier 20 requires a comparatively long time to settle the highest possible target voltage with the desired precision. This time is often not available because the duration of the first phase should not be longer than the duration of the second phase. (A longer duration of the first phase compared to the second phase would negatively affect the measurement accuracy of the conventional capacitive sensor device 10.) Therefore, the at least one measuring capacitor 12 of the conventional capacitive sensor device 10 graphically depicted in FIG. 1 often cannot be charged to an advantageously high target voltage. In addition, settling the highest possible target voltage with the desired precision must be repeated during each first phase.

### SUMMARY

The present invention provides a sensor drive device for a capacitive sensor, a capacitive sensor, and a method for operating a capacitive sensor.

The present invention provides advantageous possibilities for charging at least one measuring capacitor of a capacitive sensor to a higher target voltage within a specified time interval, while meeting a desired precision, than is possible in the related art. Because the target voltage achieved is proportional to the measurement signal of the particular capacitive sensor, the present invention also contributes to increasing a signal-to-noise ratio, for example to doubling the signal-to-noise ratio, during operation of the particular capacitive sensor. The present invention therefore also improves an operation/performance of the capacitive sensor that uses it.

As will become clear from the following description, the present invention can be implemented by means of a sensor drive device which is comparatively inexpensive and requires relatively little installation space. Use of the present invention therefore does not increase, or only negligibly increases, manufacturing costs or the dimensions of capacitive sensors. In particular, use of the present invention does not hinder, or only negligibly hinders, miniaturization of the particular capacitive sensor. The present invention can therefore be used for a variety of capacitive sensor types.

In an advantageous embodiment of the present invention, the sensor drive device comprises a first switching device, and the drive capacitor, during the first control phase, is electrically linked to the drive node via the closed first switching device, and, during the second control phase, is electrically decoupled from the drive node due to the open first switching device. Transferring/switching the first switching device from the closed state thereof to the open state thereof thus results in the target voltage being reached almost instantaneously at the at least one measuring capacitor.

Preferably, the sensor drive device comprises a control electronics unit by means of which the drive capacitor, during the second control phase, is chargeable to the drive capacitance corresponding to the target voltage, and at least the first switching device is switchable. A particular advantage of the embodiment described here is that the control electronics unit can be used to circumvent a significant disadvantage of the related art, whereby the target voltage must be stabilized by the amplifier with high precision in each first phase. Instead, the control electronics unit can be used to achieve settling to the target voltage within just a few time cycles via a discrete-time control loop, thus avoiding the conventional requirement of settling in each individual time cycle.

According to an example embodiment of the present invention, preferably, the control electronics unit comprises a differential amplifier and a control integrator, wherein during the first control phase, a control error between a predefined desired target voltage and an actual target voltage is ascertainable by means of the differential amplifier and storable in the control integrator, and during the subsequent second control phase, the drive capacitor is chargeable to the drive capacitance corresponding to the target voltage, taking the last-stored control error into account. This contributes to the reliable realization of the advantage described in the paragraph above.

As an advantageous further development of the present invention, the sensor drive device can comprise a second switching device, and the drive node, during the second control phase, can be electrically linked to a device-internal or device-external ground via the closed second switching device and, during the first control phase, can be electrically decoupled from the ground due to the open second switching device. If necessary, the second switching device can be switched in antiphase with the first switching device.

In a further advantageous development of the present invention, the sensor drive device comprises a charge pump by means of which the drive capacitor is chargeable to the drive capacitance corresponding to the target voltage during the second control phase. By using the (optional) charge pump, the achieved target voltage can be further increased.

In an advantageous embodiment of the present invention, the sensor drive device also comprises a third switching device, and the charge pump, during the second control phase, is electrically linked to the drive capacitor via the closed third switching device and, during the first control phase, is electrically decoupled from the drive capacitor due to the open third switching device. The third switching device can then be switched in phase with the second switching device and in antiphase with the first switching device.

In an alternative embodiment of the present invention, the drive capacitor is integrated into the charge pump. This can be used to miniaturize the sensor drive device or the capacitive sensor equipped therewith.

The advantages described above are also ensured in a capacitive sensor comprising such a sensor drive device according to the present invention. The capacitive sensor can, for example, be a micromechanical component and/or an acceleration sensor.

Furthermore, carrying out a corresponding method for operating a capacitive sensor according to the present invention also provides the advantages described above. It is expressly noted that the method for operating a capacitive sensor can be further developed according to the embodiments of the sensor drive device of the present invention explained above.

### BRIEF DESCRIPTION OF THE DRAWINGS

Further features and advantages of the present invention will be explained in the following with reference to the figures.

FIG. 1 is a schematic representation of a conventional capacitive sensor device.

FIG. 2 is a schematic representation of a first embodiment of the sensor drive device or the capacitive sensor cooperating therewith, according to the present invention.

FIG. 3 is a schematic representation of a second embodiment of the sensor drive device or the capacitive sensor cooperating therewith, according to the present invention.

FIG. 4 is a schematic representation of a third embodiment of the sensor drive device or the capacitive sensor cooperating therewith, according to the present invention.

FIG. 5 is a flow chart explaining an embodiment of the method for operating a capacitive sensor, according to the present invention.

### DETAILED DESCRIPTION OF EXAMPLE EMBODIMENTS

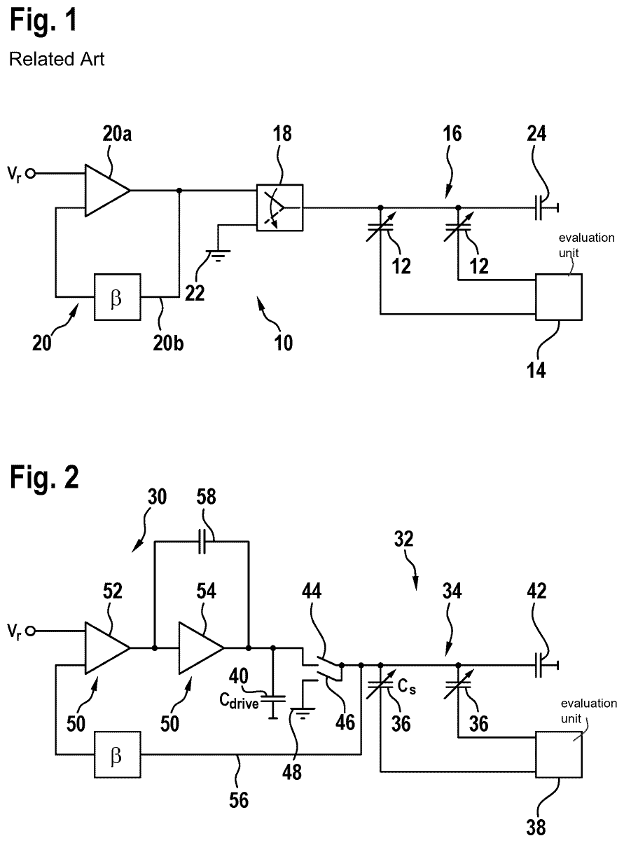

FIG. 2 is a schematic representation of a first embodiment of the sensor drive device, or the capacitive sensor cooperating therewith.

The sensor drive device 30 shown schematically in FIG. 2 can cooperate with a capacitive sensor 32. The sensor drive device 30 may optionally be a subunit of the capacitive sensor 32 or a unit operable separately/externally with respect to the capacitive sensor 32. Due to the advantageous embodiment of the sensor drive device 30 described below, the sensor drive device 30 can ensure an operability of the capacitive sensor 32 for detecting and/or measuring a variable even when it is implemented as a static capacitive sensor 32. The sensor drive device 30 thereby improves the usability of a commonly used sensor type.

The sensor drive device 30 is electrically linkable/linked to a drive node 34 of the capacitive sensor 32 in such a way that during a first control phase of the sensor drive device 30, a charge flow between the sensor drive device 30 and the drive node 34 is triggerable/triggered by means of the sensor drive device 30. By means of the charge flow between the sensor drive device 30 and the drive node 34, which is triggered during the first control phase, a predefined target voltage is able to be applied/is applied to at least one measuring capacitor 36—electrically linked to the drive node 34—of the capacitive sensor 32. In this way, the sensor drive device 30 ensures that the target voltage applied to the at least one measuring capacitor 36 is dischargeable/discharged during a second control phase of the sensor drive device 30. The discharge of at least one measuring capacitor 36 is accompanied, during the second control phase, by a flow of a measuring current Iₘ according to the equation (Eq. 1) specified above. The at least one seismic mass of the capacitive sensor 32 therefore need not execute any modulated intrinsic motion. By applying the target voltage to the at least one measuring capacitor 36 by means of the sensor drive device 30 during each first control phase, the sensor drive device 30 thus ensures that an evaluation unit 38 of the capacitive sensor 32 can determine the variable to be detected or measured during each subsequent second control phase.

Preferably, the sensor drive device 30 is alternately in the first control phase or in the second control phase. This can be understood to mean that a particular time interval between two consecutive first control phases is (completely) filled by the intermediate second control phase, and a particular time interval between two consecutive second control phases is (completely) filled by the intermediate first control phase. A first control phase and the subsequent second control phase thus form a time cycle.

The sensor drive device 30 also has a drive capacitor 40. The sensor drive device 30 is additionally configured such that during the second control phase of the sensor drive device 30, the drive capacitor 40 is chargeable/charged to a drive capacitance C_{drive} corresponding to the target voltage by means of the sensor drive device 30. Charging the drive capacitor 40 by means of the sensor drive device 30 to the drive capacitance C_{drive} corresponding to the target voltage during the particular second control phase ensures that during the subsequent first control phase, the charged drive capacitor 40 triggers the charge flow between the sensor drive device 30 and the drive node 34. Because the charging of the drive capacitor 40 takes place during the particular second control phase, the drive capacitance C_{drive} thus achieved is independent of the duration of the first control phase. In addition, by charging the drive capacitor 40 during the particular second control phase, in the subsequent first control phase, it is possible to reach the target voltage (almost) instantly through the triggered charge flow. Equipping the sensor drive device 30 with the drive capacitor 40, as described here, eliminates the conventional disadvantage that a comparatively short duration of the first control phase according to the related art leads to a limitation of the achievable target voltage. By means of the sensor drive device 30, a comparatively high target voltage can therefore be applied to the at least one measuring capacitor 36 of the capacitive sensor 32, even with a relatively short duration of each first control phase.

A measurement signal of the capacitive sensor 32 is generally proportional to the target voltage applied to the at least one measuring capacitor 36. By means of the increase in the target voltage made possible by equipping the sensor drive device 30 with the drive capacitor 40, an increase in the measurement signal of the capacitive sensor 32 can also be achieved compared to its relative level. In this way, a signal-to-noise ratio of the capacitive sensor 32 can be increased. In particular, by increasing the target voltage applied to the at least one measuring capacitor 36, it is often possible to achieve at least a doubling of the signal-to-noise ratio of the capacitive sensor 32. This makes it possible to evaluate measurement signals from the capacitive sensor 32 using an evaluation electronics unit 38 which is more cost-effective and requires less installation space. In addition, increasing the signal-to-noise ratio of the capacitive sensor 32 compared to the related art often results in increased measurement accuracy and/or improved measurement reliability of the capacitive sensor 32.

It is expressly noted here that, unlike the related art described above, equation (Eq. 2) for the embodiment of FIG. 2 does not specify any settling time t required for the target voltage to settle with a desired precision. This also eliminates the conventional need to design the sensor drive device 30 to have a specific conductance g or a special feedback factor β to limit the settling time t. Even a parasitic capacitance Cₚ of at least one interference capacitor 42 of the capacitive sensor 32 has no, or virtually no, influence on the achievable target voltage. By equipping the sensor drive device 30 with the drive capacitor 40 thereof, an increase in the achievable target voltage can therefore be implemented relatively easily compared to the related art.

In the embodiment of FIG. 2, the sensor drive device 30 has a first switching device 44 which is switchable/switched in such a way that the drive capacitor 40, during the first control phase, is electrically linked to the drive node 34 via the closed first switching device 44. Also preferred is a switching of the first switching device 44 that ensures that the drive capacitor 40, during the second control phase, is electrically decoupled from the drive node 34 due to the open first switching device 44.

Optionally, the sensor drive device 30 may also comprise a second switching device 46. Preferably, the second switching device 46 is switchable/switched in such a way that the drive node 34, during the second control phase, is electrically linked to a device-internal or device-external ground 48 via the closed second switching device 46, but, during the first control phase, is electrically decoupled from the ground 48 due to the open second switching device 46. The second switching device 46 can thus be switched in antiphase and in synchronism with the first switching device 44. However, it should also be noted that configuring the sensor drive device 30 with the second switching device 46 and possibly the ground 48 is optional. For example, even if the sensor drive device 30 is provided as a unit which is operable separately/externally with respect to the capacitive sensor 32, the second switching device 46 and the ground 48 may be components of the capacitive sensor 32.

A particular advantage of the sensor drive device 30 of FIG. 2 is the configuration thereof with a control electronics unit 50, by means of which the drive capacitor 40, during the second control phase, is chargeable/charged to the drive capacitance C_{drive} corresponding to the target voltage. The first switching device 44 and possibly the second switching device 46 can also be switchable/switched by means of the control electronics 50.

The control electronics unit 50 comprises a differential amplifier 52 and a control integrator 54. A first signal input of the differential amplifier 52 is electrically linked to the drive node 34 via a feedback line 56 with the feedback factor β. Preferably, the feedback factor β is implemented purely capacitively. A reference voltage Vᵣ is applied to a second signal input of the differential amplifier 52. The differential amplifier can therefore ascertain a control error between a predefined desired target voltage and an (actually) achieved actual target voltage during the first control phase.

A signal output of the differential amplifier 52 is electrically linked to a signal input of the control integrator 54. Thus, the control error between the desired target voltage and the actual target voltage, which is ascertained by means of the differential amplifier 52, is storable in the control integrator 54. During the subsequent second control phase, the drive capacitor 40 can be charged to the drive capacitance C_{drive} corresponding to the target voltage, taking the last-stored control error into account, in such a way that the predefined desired target voltage is maintained more reliably.

The control electronics unit 50 thus has an “integrated mechanism” which, via a time-discrete control loop, allows settling to the drive capacitance C_{drive} within just a few time cycles (each time cycle comprising the first control phase and the subsequent second control phase). During the time cycles following the settling to the drive capacitance C_{drive} achieved by means of a few time cycles, no further settling to the drive capacitance C_{drive} is required. This eliminates the requirement of the above-mentioned related art for settling to the target voltage within each individual time cycle. This can also be used to advantageously increase the achievable target voltage while maintaining an advantageous precision. Furthermore, by eliminating the need to settle to the target voltage within each individual time cycle, substantial power savings are possible during operation of the capacitive sensor 32 together with the sensor drive device 30. These power savings can be used in addition to the implementation of a comparatively large sensor capacitance Cₛ of the at least one measuring capacitor 36. Because the sensor capacitance Cₛ of the at least one measuring capacitor 36 varies as a function of the variable to be detected or measured by means of the capacitive sensor 32, increasing the sensor capacitance Cₛ also allows the measurement accuracy and/or the measurement reliability of the capacitive sensor 32 to be improved.

Preferably, the control integrator 54 has an (approximately) infinite gain in the case of DC (i.e., at a frequency equal to zero Hertz). In steady state, the drive node 34 is therefore at a quotient of the reference voltage Vᵣ divided by β in order to satisfy the loop condition in the case of DC. A slewing/settling error at the signal output of the control integrator 54 can be corrected by a loop 58 of the control electronics unit 50. The slewing/settling error is therefore (approximately) zero. Optionally, a source follower (not shown) and/or an impedance transformer (not outlined) can be arranged downstream of the signal output of the control integrator 54 in order to allow more effective settling of the control integrator 54.

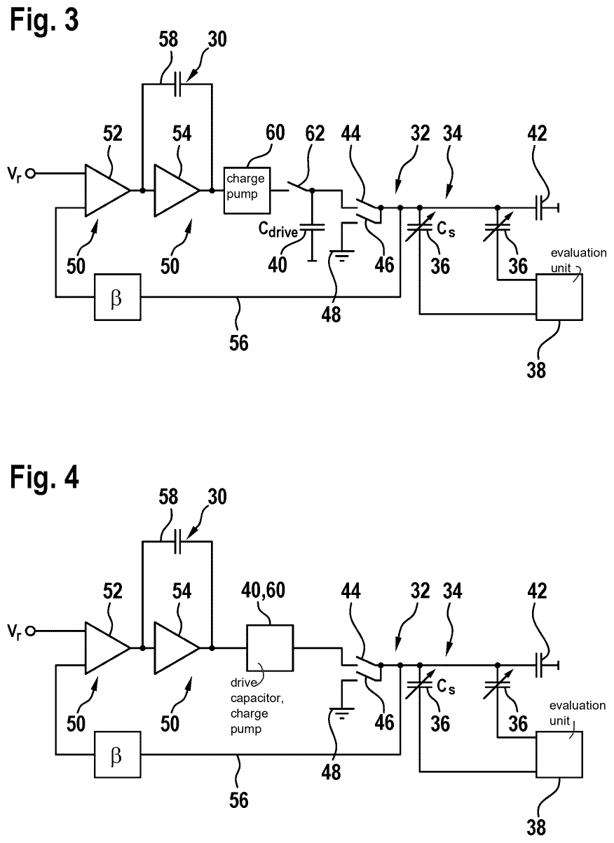

FIG. 3 is a schematic representation of a second embodiment of the sensor drive device, or the capacitive sensor cooperating therewith.

The sensor drive device 30 shown schematically in FIG. 3 also has a charge pump 60 as a further development of the embodiment described above. Advantageously, the signal output of the control integrator 54 is linked to the charge pump 60, the signal output of which is linkable/linked to the drive capacitor 40 of the sensor drive device 30 of FIG. 3. Thus, the drive capacitor 40 of the sensor drive device 30 of FIG. 3 can also be charged by means of the charge pump 60 to the drive capacitance C_{drive} corresponding to the target voltage during the second control phase. The use of the charge pump 60 not only accelerates the charging of the drive capacitor 40 to the drive capacitance C_{drive} corresponding to the target voltage, but also allows an additional increase in the achievable target voltage. In particular, it is possible, by means of the charge pump 60, to multiply the achievable target voltage using a supply voltage.

The charge pump 60 can, for example, be an SC circuit (switched capacitor circuit). In particular, the charge pump 60 can be operated at a multiple frequency of a desired readout pulse of the capacitive sensor 32 in order to charge the drive capacitor 40 to the drive capacitance C_{drive} corresponding to the target voltage. After the drive capacitor 40 is charged to the drive capacitance C_{drive} corresponding to the target voltage, a short circuit of the drive node 34 can be effected by closing the first switching device 44. The capacitances of the charge pump 60 may be such that the short circuit caused by closing the first switching device 44 does not cause a major voltage loss. The desired target voltage is then automatically regulated.

Merely by way of example, the sensor drive device 30 of FIG. 3 (in addition to switching devices 46 and 48) also has a third switching device 62 which is connected between the charge pump 60 and the drive capacitor 40. Preferably, the third switching device 62 is connected in such a way that the charge pump 60, during the second control phase, is electrically linked to the drive capacitor 40 via the closed third switching device 62, and, during the first control phase, is electrically decoupled from the drive capacitor 40 due to the open third switching device 62. The third switching device 62 can thus be switched in synchronism with the first switching device 44 and the second switching device 46, and in antiphase with the first switching device 44 but in phase with the second switching device 46. The switching of the third switching device 62 is executable/executed by means of the control electronics unit 50.

With regard to further features and properties of the sensor drive device 30 of FIG. 3, reference is made to the above-described embodiment of FIG. 2.

FIG. 4 is a schematic representation of a third embodiment of the sensor drive device, or the capacitive sensor cooperating therewith.

In contrast to the embodiment of FIG. 3, in the sensor drive device 30 of FIG. 4 the drive capacitor 40 is integrated into the charge pump 60. Accordingly, equipping the sensor drive device 30 of FIG. 4 with a third switching device 62 may be dispensed with.

With regard to further features and properties of the sensor drive device 30 of FIG. 4, reference is made to the embodiments of FIGS. 2 and 3.

In all embodiments described above, the capacitive sensor 32 is preferably a micromechanical component. In particular, the capacitive sensor 32 can be a capacitive MEMS baseband sensor in which the at least one seismic mass of the capacitive sensor 32 does not execute any modulated intrinsic motion. Because the capacitive sensor 32 has an improved signal-to-noise ratio compared to the related art, the capacitive sensor 32 can in particular also be an acceleration sensor, specifically an acceleration sensor of a structure-borne sound microphone. For example, the acceleration sensor in a headset can be used to record a user's speech in a low-frequency range which is hardly disturbed by external noise sources.

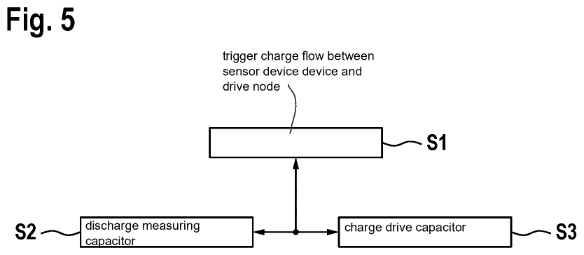

FIG. 5 is a flow chart explaining an embodiment of the method for operating a capacitive sensor.

It should be noted that the feasibility of the method described below is not limited to any particular type of capacitive sensor. In particular, the capacitive sensor can also be static, i.e., at least one seismic mass of at least one measuring capacitor of the capacitive sensor does not execute any modulated intrinsic motion.

When carrying out the method, a sensor drive device electrically linkable or linked to a drive node of the capacitive sensor is operated alternately in a first control phase or in a second control phase.

During the first control phase of the sensor drive device, as method step S1, a charge flow between the sensor drive device and the drive node is triggered by means of the sensor drive device in such a way that a predefined target voltage is applied to at least one measuring capacitor—electrically linked to the drive node—of the capacitive sensor. For example, the charge flow can be triggered by closing and keeping closed a first switching device of the sensor drive device in method step S1.

During the second control phase of the sensor drive device, the at least one measuring capacitor is discharged in a method step S2. This can be achieved by closing and keeping closed a second switching device of the sensor drive device, via which the at least one measuring capacitor is electrically linked to a ground.

In addition, during the second control phase, a method step S3 is also carried out, in which a drive capacitor of the sensor drive device is charged by means of the sensor drive device to a drive capacitance corresponding to the target voltage. Provided that, in method step S1, the drive capacitor is electrically linked to the drive node via the first switching device, which is closed and kept closed, the charged drive capacitor (automatically) triggers, during the subsequent first control phase, the charge flow between the sensor drive device and the drive node.

In this way, carrying out the method steps S1 to S3 explained here also achieves the advantages mentioned above.

1-11. (canceled)

12. A sensor drive device for a capacitive sensor, wherein the sensor drive device is electrically linkable or linked to a drive node of the capacitive sensor in such a way that during a first control phase of the sensor drive device, a charge flow between the sensor drive device and the drive node is triggerable using the sensor drive device in such a way that a predefined target voltage is able to be applied to at least one measuring capacitor, electrically linked to the drive node, of the capacitive sensor, which is dischargeable during a second control phase of the sensor drive device, the sensor drive device comprising:
a drive capacitor, wherein during the second control phase of the sensor drive device, the drive capacitor is chargeable using the sensor drive device to a drive capacitance corresponding to the target voltage, in such a way that during a subsequent first control phase, the charged drive capacitor triggers the charge flow between the sensor drive device and the drive node.

13. The sensor drive device according to claim 12, further comprising:
a first switching device, wherein the drive capacitor, during the first control phase, is electrically linked to the drive node via the first switching device in a closed state, during the second control phase, is electrically decoupled from the drive node due to the first switching device in an open state.

14. The sensor drive device according to claim 13, further comprising:
a control electronics unit using which the drive capacitor, during the second control phase, is chargeable to the drive capacitance corresponding to the target voltage, and at least the first switching device is switchable.

15. The sensor drive device according to claim 14, wherein the control electronics unit includes a differential amplifier and a control integrator, wherein during the first control phase, a control error between a predefined desired target voltage and an actual target voltage is ascertainable using the differential amplifier and storable in the control integrator, and during a subsequent second control phase, the drive capacitor is chargeable to the drive capacitance corresponding to the target voltage, taking a last-stored control error into account.

16. The sensor drive device according to claim 12, further comprising:
a second switching device, wherein the drive node, during the second control phase, is electrically linked to a device-internal or device-external ground via the second switching device in a closed state, and, during the first control phase, is electrically decoupled from the ground due to the second switching device in an open state.

17. The sensor drive device according to claim 12, further comprising:
a charge pump using which the drive capacitor is chargeable to the drive capacitance corresponding to the target voltage during the second control phase.

18. The sensor drive device according to claim 17, further comprising:
a third switching device, wherein the charge pump, during the second control phase, is electrically linked to the drive capacitor via the third switching device in a closed state, and, during the first control phase, is electrically decoupled from the drive capacitor due to the third switching device in the open state.

19. The sensor drive device according to claim 17, wherein the drive capacitor is integrated into the charge pump.

20. A capacitive sensor, comprising:
a sensor drive device electrically linkable or linked to a drive node of the capacitive sensor in such a way that during a first control phase of the sensor drive device, a charge flow between the sensor drive device and the drive node is triggerable using the sensor drive device in such a way that a predefined target voltage is able to be applied to at least one measuring capacitor, electrically linked to the drive node, of the capacitive sensor, which is dischargeable during a second control phase of the sensor drive device, the sensor drive device comprising:
a drive capacitor, wherein during the second control phase of the sensor drive device, the drive capacitor is chargeable using the sensor drive device to a drive capacitance corresponding to the target voltage, in such a way that during a subsequent first control phase, the charged drive capacitor triggers the charge flow between the sensor drive device and the drive node.

21. The capacitive sensor according to claim 20, wherein the capacitive sensor is a micromechanical component and/or an acceleration sensor.

22. A method for operating a capacitive sensor, comprising the following steps:
operating a sensor drive device which is electrically linkable or linked to a drive node of the capacitive sensor in such a way that during a first control phase of the sensor drive device, a charge flow between the sensor drive device and the drive node is triggered using the sensor drive device in such a way that a predefined target voltage is applied to at least one measuring capacitor, electrically linked to the drive node, of the capacitive sensor, which is discharged during a second control phase of the sensor drive device;
wherein during the second control phase, a drive capacitor of the sensor drive device is charged to a drive capacitance corresponding to the target voltage using the sensor drive device, in such a way that during a subsequent first control phase, the charged drive capacitor triggers the charge flow between the sensor drive device and the drive node.
